(19) United States
(12) Patent Application Publication
(10) Pub. No.: US 2007/0134917 A1
(43) Pub. Date: Jun. 14, 2007

(54) Partial-via-first dual-damascene process with tri-layer resist approach

(75) Inventors: Tsai-Chun Li, Hsinchu (TW); Tsang-Jiuh Wu, Hsinchu (TW); Hui Ouyang, Hsinchu (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Taiwan Semiconductor Manufacturing Co., Ltd.

(21) Appl. No.: 11/301,917

(22) Filed: Dec. 13, 2005

(51) Int. Cl. H01L 21/4763

(52) U.S. Cl. 438/637

(57) ABSTRACT

A partial-via-first dual-damascene method using a tri-layer resist method forms a first via hole through partial thickness of a dielectric layer, and forms a tri-layer resist structure on the dielectric layer to fill the first via hole with the bottom photoresist layer. A dry development process is performed to transfer a first opening on the top photoresist layer to the middle layer and the bottom photoresist layer, and expose the first via hole again, and remove the top photoresist layer. A dry etching process is then performed to form a second via hole under the first via hole and a trench over the second via hole. Finally a wet striping process is used to remove the remainder of the photoresist layer.

### TECHNICAL FIELD

The present invention relates to the fabrication of structures for integrated circuit devices, and particularly to a partial-via-first dual-damascene process using a tri-layer resist approach.

### BACKGROUND

Dual-damascene interconnect features are advantageously used to provide planarized interconnect structures that afford the use of multiple interconnect layers and therefore increase levels of device integration. There is a trend in the semiconductor industry towards the use of low-dielectric constant (low-k) dielectric materials, particularly used in conjunction with copper conductive lines, to reduce the RC time delay of the conductive lines. Some low-k dielectric materials are porous, and it is difficult to adequately control the etch process, particularly in the dual-damascene structure and process.

Dual-damascene methods include either a “via-first” patterning methods in which via holes are first patterned in the insulating layer through the entire thickness of the insulating layer, and then trenches are patterned in a top portion of the insulating layer. Or, the trenches may alternatively be patterned in a top portion of the insulating layer first, followed by the patterning of the via holes through the insulating layer, called “trench-first” patterning methods. A lithography method in which a mask is transferred into a photoresist on a substrate with an exposure step is typically used to define via holes and trenches in the dual-damascene structure. Photoresist poisoning, however, tends to be a problem in the full-via-first dual-damascene process because of the subsequent photoresist exposed to amines generated during the previous etch process. One approach using a tri-layer resists (TLR) scheme has been introduced in an attempt to overcome the difficulties associated with the photoresist resistant to poisoning, but problems of photoresist ashing damages, coating micro-loading effect, and wet strip ability in via holes are always accompanied. The other approach of using a metal hardmask has been applied to the trench-first dual-damascene process for preventing plasma damages in photoresist stripping, but via misalignment and metallic polymer removal are the disadvantages of this approach.

Accordingly, there is a need for a novel dual-damascene process which overcomes difficulties associated with the tri-layer resist process and the metal hard mask process to provide a wide wet strip window in the via holes without extra process flow and production cost.

### SUMMARY OF THE INVENTION

Embodiments of the present invention include a partial-via-first dual-damascene method using a tri-layer resist process to improve critical-dimension control for via holes and trench, avoid ashing damage, and provide a wide wet strip window in patterning via holes without extra process flow and production costs.

In one aspect, the present invention provides a partial-via-first dual-damascene process having the steps of: forming a dielectric layer over a semiconductor substrate; forming a first via hole through partial thickness of the dielectric layer; forming a tri-layer resist structure on the dielectric layer, wherein the tri-layer resist structure comprises a bottom layer overlying the dielectric layer and filling the first via hole, a middle layer overlying the bottom layer, and a top layer overlying the middle layer and having a first opening; performing a dry development process to transfer the first opening to the middle layer and the bottom layer and remove the bottom layer remaining in the first via hole, wherein the first via hole is exposed and the top layer is removed; performing a dry etching process to remove at least part of the dielectric layer to form a second via hole under the first via hole and form a trench over the second via hole, wherein the middle layer is removed; and performing a wet striping process to remove the bottom layer.

In another aspect, the present invention provides a dual-damascene process having the steps of: providing a semiconductor substrate comprising a conductive region; forming an etch stop layer on the semiconductor substrate; forming a dielectric layer on the etch stop layer, wherein the dielectric layer comprising a first via hole located at the upper portion of the dielectric layer having a depth less than one half of the thickness of the dielectric layer; forming a bottom photoresist layer on the dielectric layer, wherein the bottom photoresist layer fills the first via hole to form a plug; forming an anti-reflective coating (ARC) layer on the bottom photoresist layer; forming a top photoresist layer on the ARC layer, wherein the top photoresist layer comprises a first opening over the first via hole; performing a dry development process to transfer the first opening to the ARC layer and the bottom photoresist layer and clean the plug, wherein the first via hole is exposed and the top photoresist layer is removed; performing a dry etching process to remove at least part of the dielectric layer to form a second via hole under the first via hole and form a trench over the second via hole, wherein the second via hole exposes at least part of the conductive region and the ARC layer is removed; and performing a wet striping process to remove the remainder of the bottom photoresist layer.

### BRIEF DESCRIPTION OF THE DRAWINGS

The aforementioned objects, features and advantages of this invention will become apparent by referring to the following detailed description of the preferred embodiments with reference to the accompanying drawings, wherein:

FIG. 1 to FIG. 5 are cross-sectional diagrams illustrating an embodiment of a partial-via-first dual-damascene method using a tri-layer resist process.

### DETAILED DESCRIPTION OF ILLUSTRATIVE EMBODIMENTS

Embodiments of the present invention provide a novel dual-damascene process, which overcomes the aforementioned problems of the prior art through the use of a tri-layer resist process and a metal hard mask process. Particularly, a partial-via-first dual-damascene method with a tri-layer resist process is employed to improve critical-dimension (CD) control for via holes and trenches, avoid ashing damage, and provide a wide wet strip window in patterning via holes without extra process flow and production costs. Compared with the conventional full-via-first method, the term “partial-via-first” as used throughout this disclosure refers to a dual-damascene method in which an initial via hole is patterned first through partial thickness of a dielectric layer by reducing the depth of the initial via etch, and then a real via hole is patterned in the lower portion of the dielectric layer and a trench is patterned in the upper portion of the dielectric layer.

Reference will now be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, apparatus in accordance with the present invention. It is to be understood that elements not specifically shown or described may take various forms well known to those skilled in the art. Further, when a layer is referred to as being on another layer or “on” a substrate, it may be directly on the other layer or on the substrate, or intervening layers may also be present.

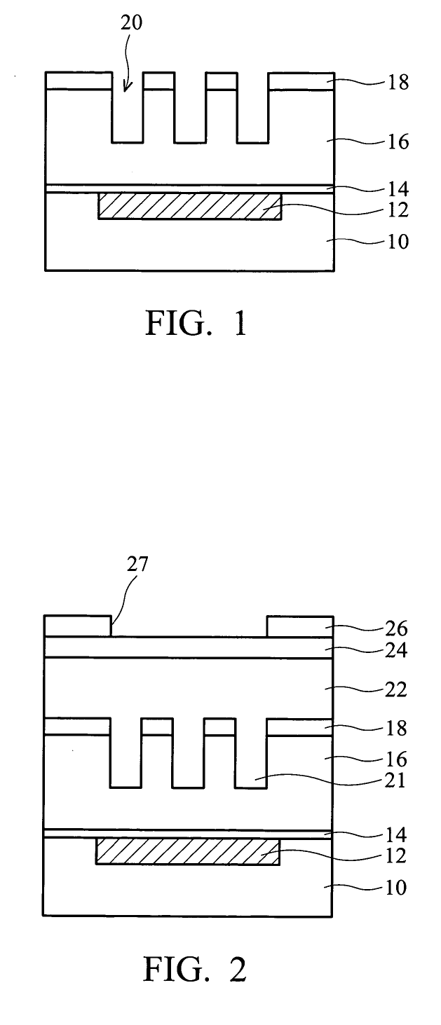

Herein, cross-sectional diagrams of FIG. 1 to FIG. 5 illustrate an exemplary embodiment of a partial-via-first dual-damascene method using a tri-layer resist process. In FIG. 1, an example of a substrate 10 used for interconnection fabrication may comprise a semiconductor substrate as employed in a semiconductor integrated circuit fabrication, and integrated circuits may be formed therein and/or thereupon. The semiconductor substrate is defined to mean any construction comprising semiconductor materials, including, but is not limited to, bulk silicon, a semiconductor wafer, a silicon-on-insulator (SOI) substrate, or a silicon germanium substrate. The integrated circuits as used herein refer to electronic circuits having multiple individual circuit elements, such as transistors, diodes, resistors, capacitors, inductors, and other active and passive semiconductor devices. The substrate 10 comprises a conductive region 12, which is a portion of conductive routes and has an exposed surface treated by a planarization process, such as chemical mechanical polishing (CMP), if necessary. Suitable materials for the conductive region 12 may include, but are not limited to, for example copper, aluminum, copper-based alloy, or other mobile conductive materials.

An etch stop layer 14 deposited on the substrate 10 may be formed of silicon oxide, silicon nitride, silicon carbide, silicon oxynitride or combinations thereof, with a thickness of about 10 angstroms to about 1000 angstroms, which may be formed through any of a variety of deposition techniques, including, LPCVD (low-pressure chemical vapor deposition), APCVD (atmospheric-pressure chemical vapor deposition), PECVD (plasma-enhanced chemical vapor deposition), PVD (physical vapor deposition), sputtering, and future-developed deposition procedures.

An inter-layer-dielectric (ILD) layer 16 formed on the etch stop layer 14 reaches a thickness of about 500 angstroms to about 30000 angstroms through any of a variety of techniques, including, spin coating, CVD, and future-developed deposition procedures. The ILD layer 16 may be a single layer or a multi-layered structure. The ILD layer 16 is formed of a comparatively low dielectric constant dielectric material with a k value less than about 3.9, e.g., 3.5, 3.0 or less. A wide variety of low-k materials may be employed in accordance with embodiments of the present invention, for example, spin-on inorganic dielectrics, spin-on organic dielectrics, porous dielectric materials, organic polymer, organic silica glass, fluorinated silicate glass (FSG), diamond-like carbon, HSQ (hydrogen silsesquioxane) series material, MSQ (methyl silsesquioxane) series material, porous organic series material, polyimides, polysilsesquioxanes, polyarylethers, fluorosilicate glass, and commercial materials such as FLARE from Allied Signal or SiLK from Dow Corning, and other low k dielectric compositions.

An optional cap layer 18 may be deposited on the ILD layer 16, which also relieves stress in ILD layer 16. The optional cap layer 18 may be tetra-ethyl-ortho-silicate (TEOS) based oxides, inorganic oxide, silicon nitride, silicon oxynitride or silicon carbide, having a thickness in the range of about 50 to 2000 Angstroms formed through any of a variety of deposition techniques including LPCVD, APCVD, PECVD, PVD, sputtering and future-developed deposition procedures.

Referring to FIG. 1, at least one initial via hole 20 is formed in the dielectric stack by using typical lithography with masking technologies and anisotropic etch operation (e.g. plasma etching or reactive ion etching) to transfer an opening in a photoresist (not shown) through the optional cap layer 18 and partial thickness of the ILD layer 16. The photoresist is then removed by a conventional wet strip process. A wet cleaning step may be added to ensure that no residues remain on the cap layer 18 and/or the exposed ILD layer 16. The initial via hole 20 may reach a depth less than about one half of the thickness of the ILD layer 16. For example, the depth is about ¼˜½ of the thickness of the ILD layer 16, without exposing the etch stop layer 14 and the conductive region 12. Although FIG. 1 illustrates more than one initial via holes 20, the present invention also provides value when forming only one initial via hole for forming a dual-damascene opening.

In FIG. 2, a composite resist layer is provided on the substrate 10, forming a tri-layer resist scheme. The tri-layer resist scheme comprises a bottom layer 22 that is formed on the optional cap layer 18 and the ILD layer 16 to fill the initial via holes 20, a middle layer 24 formed on the bottom layer 22, and a top layer 26 with an opening 27 formed on the middle layer 24.

The bottom layer 22 is spin coated and baked in a temperature to form a film about 50 to 20000 Angstroms, which fills the initial via holes 20 to form plugs 21 respectively. The bottom layer 22 contains a polar component such as a polymer with hydroxyl or phenol groups that can attract or bond with amines or nitrogen containing compounds that might diffuse out of the underlying dielectric materials. In one embodiment, the bottom layer 22 is an i-line photoresist that normally includes a Novolac resin that is prepared by reacting a cresol, xylenol, or other substituted phenols with formaldehyde. The i-line photoresist is particularly useful in preventing amines such as ammonia from reaching an overlying photoresist that is exposed to produce a pattern. Alternatively, the bottom layer 22 may be a deep UV photoresist that typically includes polymers having hydroxystyrene groups. The bottom layer 22 may be formed from either a positive tone or negative tone photoresist. The material selected for the bottom layer 22 is conveniently one that is already used in the manufacturing line in order to avoid the cost of implementing new materials.

The middle layer 24 is formed by spin coating and baking, reaching a thickness about 300 Angstroms to 1000 Angstroms. The middle layer 24 functions as an anti-reflective coating (ARC), which prevents the light from reaching the underlying resist layer during the time when the overlying photoresist layer is exposed. Also, the middle layer 24 may be selected from a material that is immiscible with organic solvents used for subsequently resist coating and/or has optical properties minimizing reflectivity of light during exposure of photoresist. For example, the middle layer 24 may be a negative organic ARC, a negative dyed resist, a Deep UV ARC, or a 193 nm ARC.

The top layer 26 is a photoresist selected depending upon the size of the trench. For example, a deep UV photoresist is used for printing feature sizes in a range from about 130 nm to about 250 nm, and 193 nm photoresist is desired for printing features with a size between about 100 nm and 130 nm. The thickness of photoresist is in a range from about 2000 Angstroms to about 8000 Angstroms depending on the width of trench. The photoresist may be either a positive tone or a negative tone material, which is then exposed and developed in an aqueous base solution to form the opening 27. The opening 27 corresponds in position and dimension to the initial via holes 20 and will be transferred to the underlying resist layers for defining a trench in subsequent processes.

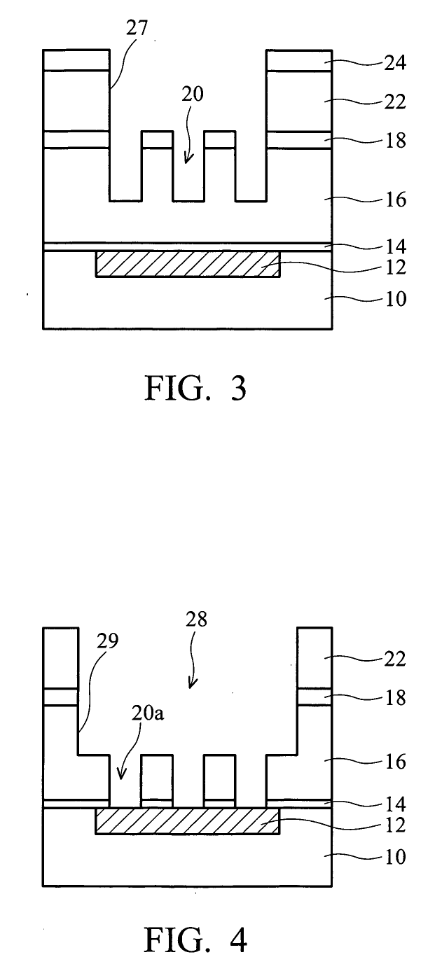

In FIG. 3, the opening 27 is transferred through the middle layer 24 and the bottom layer 22 by a dry development while the plugs 21 are cleaned to expose the initial via holes 20 again. This dry development also removes the top layer 26, thus saving one step of photoresist ashing and preventing conventional dry ashing damages.

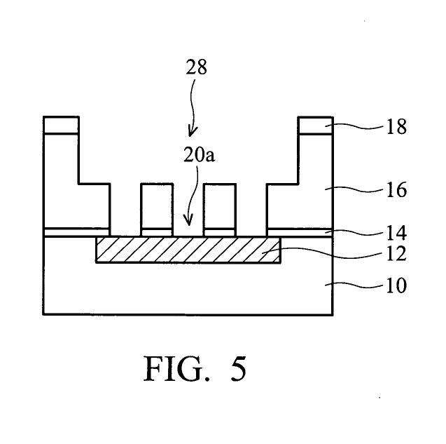

Next, in FIG. 4, using a dry etch process with an etch gas comprising CF₄, Ar and O₂ in the same chamber, the ILD layer 16 and the etch stop layer 14 under the initial via holes 20 are etched to form final via holes 20a respectively, thus exposing the conductive region 12. Also, the optional cap layer 18 and the ILD layer 16 surrounding the initial via holes 20 are laterally etched in-situ to form a trench 28 over the final via holes 20a. During the dry etch process through the optional cap layer 18 and the ILD layer 16, the middle layer 24 and the bottom layer 22 are typically consumed, and the middle layer 24 may be removed. Therefore, the trench 28 is formed in the upper portion of the ILD layer 16, and the final via holes 20a are formed in the lower portion of the ILD layer 16, completing a dual-damascene opening. Particularly, vertical sidewalls 29 and roughness-free surface can be achieved on the trench 28. Finally, in FIG. 5, the remainder of the bottom layer 22 is removed from the optional cap layer 18 through a wet strip process with a wet solution comprising a mixture of H₂SO₄ and H₂O₂, or a mixture of sulfuric acid and nitric acid. Although figures illustrate more than one final via holes, the present invention also provides value when forming only one final via hole for forming a dual-damascene opening.

Accordingly, the inventive method has the following advantages. First, using the tri-layer resist process to partially open the initial via hole first can control trench CD and depth loading and minimize micro-loading effect of subsequent resist coating, thus having ability to CD reduction for the via hole and the trench. Second, the use of the tri-layer resist development for defining the trench CD and clean the plug and removing the top layer of photoresist can obtain poison-via free, low risk for mean-time-between-clean (MTBC) and wide wet strip window. Also the removal of the photoresist during the dry development can avoid dry ashing damage. Third, the dry etch for in-situ defining the trench and via holes can obtain substantially vertical sidewalls and roughness-free surface on the trench, and achieve nature corner rounding. Fourth, compared with the conventional full-via-first dual-damascene process and metal hard mask process, this partial-via-first dual-damascene method with the tri-layer resist process is simpler without extra, process flow and production costs.

Although the present invention has been described in its preferred embodiments, it is not intended to limit the invention to the precise embodiments disclosed herein. Those skilled in this technology can still make various alterations and modifications without departing from the scope and spirit of this invention. Therefore, the scope of the present invention shall be defined and protected by the following claims and their equivalents.

What is claimed is:

1. A partial-via-first dual-damascene process, comprising:
forming a dielectric layer overlying a semiconductor substrate;
forming a first via hole through partial thickness of said dielectric layer;
forming a tri-layer resist structure on said dielectric layer, wherein said tri-layer resist structure comprises a bottom layer overlying said dielectric layer and filling said first via hole, a middle layer overlying said bottom layer, and a top layer overlying said middle layer and having an opening;
performing a dry development process to transfer said opening to said middle layer and said bottom layer and remove said bottom layer from said first via hole, wherein said first via hole is exposed and said top layer is removed;
performing a dry etching process to remove at least part of said dielectric layer to form a second via hole under said first via hole and form a trench over said second via hole, wherein said middle layer is removed; and
performing a wet striping process to remove said bottom layer.

2. The partial-via-first dual-damascene process of claim 1, wherein said first via hole has a depth less than one half of the thickness of said dielectric layer.

3. The partial-via-first dual-damascene process of claim 1, wherein said bottom layer comprises an i-line photoresist.

4. The partial-via-first dual-damascene process of claim 1, wherein said middle layer comprises an anti-reflective coating film.

5. The partial-via-first dual-damascene process of claim 1, wherein said top layer comprises photoresist.

6. The partial-via-first dual-damascene process of claim 1, wherein said dry etching process removes the lower portion of said dielectric layer exposed by said first via hole to form said second via hole, and removes the upper portion of said dielectric layer under said opening around said first via hole to form said trench.

7. The partial-via-first dual-damascene process of claim 1, wherein said dielectric layer has a dielectric constant less than about 3.9.

8. The partial-via-first dual-damascene process of claim 1, further comprising forming an etch stop layer between said semiconductor substrate and said dielectric layer, wherein said second via hole passes through the lower portion of said dielectric layer and said etch stop layer.

9. The partial-via-first dual-damascene process of claim 8, wherein said etch stop layer comprises silicon nitride, silicon oxynitride, silicon carbide, or combinations thereof.

10. The partial-via-first dual-damascene process of claim 1, further comprising forming a cap layer on said dielectric layer before forming said first via hole, wherein the formation of said first via hole passes through said cap layer and the upper portion of said dielectric layer.

11. The partial-via-first dual-damascene process of claim 10, wherein said cap layer comprises tetra-ethyl-ortho-silicate (TEOS) based oxide.

12. The partial-via-first dual-damascene process of claim 1, wherein said semiconductor substrate comprises a conductive region, and the formation of said second via hole exposes at least part of said conductive region.

13. The partial-via-first dual-damascene process of claim 12, wherein said conductive region comprises copper or copper-based alloy.

14. The partial-via-first dual-damascene process of claim 1, wherein said dry etching process forms said trench with a substantially vertical sidewall.

15. A dual-damascene process, comprising:
providing a semiconductor substrate comprising a conductive region;
forming an etch stop layer on said semiconductor substrate;
forming a dielectric layer on said etch stop layer, wherein said dielectric layer comprises a first via hole located at the upper portion of said dielectric layer and having a depth less than one half of the thickness of said dielectric layer;
forming a bottom photoresist layer on said dielectric layer, wherein said bottom photoresist layer fills said first via hole to form a plug;
forming an anti-reflective coating (ARC) layer on said bottom photoresist layer;
forming a top photoresist layer on said ARC layer, wherein said top photoresist layer comprises an opening over said first via hole;
performing a dry development process to transfer said opening to said ARC layer and said bottom photoresist layer and remove said plug, wherein said first via hole is exposed and said top photoresist layer is removed;
performing a dry etching process to remove at least part of said dielectric layer to form a second via hole under said first via hole and form a trench over said second via hole, wherein said second via hole exposes at least part of said conductive region and said ARC layer is removed; and
performing a wet striping process to remove the remainder of said bottom photoresist layer.

16. The dual-damascene process of claim 15, wherein said bottom layer comprises an i-line photoresist.

17. The dual-damascene process of claim 15, wherein said dry etching process removes the lower portion of said dielectric layer exposed by said first via hole to form said second via hole, and removes the upper portion of said dielectric layer under said opening around said first via hole to form said trench.

18. The dual-damascene process of claim 15, wherein said dielectric layer has a dielectric constant less than about 3.9.

19. The dual-damascene process of claim 15, further comprising forming a cap layer on said dielectric layer before forming said first via hole, wherein the formation of said first via hole passes through said cap layer and the upper portion of said dielectric layer.

20. The dual-damascene process of claim 15, wherein said dry etching process forms said trench with a substantially vertical sidewall.
